(19) United States
(12) Patent Application Publication
(10) Pub. No.: US 2009/0121756 A1
(43) Pub. Date: May 14, 2009

(54) PSEUDO-SYNCHRONOUS SMALL REGISTER DESIGNS WITH VERY LOW POWER CONSUMPTION AND METHODS TO IMPLEMENT

(75) Inventors: Manoj Chandran, Chandler, AZ (US); Jay Lory, Chandler, AZ (US)

Correspondence Address: NXP, B.V.;NXP INTELLECTUAL PROPERTY DEPARTMENT, M/S41-SJ, 1109 MCKAY DRIVE, SAN JOSE, CA, 95131, US

(73) Assignee: NXP B.V., Eindhoven (NL)

(21) Appl. No.: 12/294,010

(22) PCT Filed: Mar. 20, 2007
(86) PCT No.: PCT/IB2007/050976

§ 371 Date: Sep. 22, 2008

Related U.S. Application Data
(60) Provisional application No. 60/784,641, filed on Mar. 21, 2006.

(51) Int. Cl. H03L 7/00

(52) U.S. Cl. 327/144

(57) ABSTRACT

Methods and apparatus for implementing and operating one or more pseudo-synchronous registers with reduced power consumption, and reduced complexity for transferring data between clock domains. Various embodiments of the present invention replace conventional continuous clocking schemes with a strobe signal that is only generated when a data transfer operation with the one or more pseudo-synchronous registers is to take place. The strobe signal is generated so as to have a duration of one full cycle of the clock signal which defines the clock domain in which the at least one pseudo-synchronous register resides.

The present invention relates generally to methods and apparatus for reducing power consumption and improving reliability in data transfers across clock domain boundaries.

Digital circuits and components have become ubiquitous in electronic products and systems as the cost of producing integrated circuits has declined, and as the variety of available components has increased.

Almost all digital systems include circuits for storing information, and such information in digital systems is typically referred to as bits. There are a number of circuit configurations that provide for storage of bits. One often-used class of circuits for storing bits is the bi-stable multivibrator, which is most commonly referred to as a flip-flop. Flip-flops, latches, storage bits, or similarly named circuits that are used for storing bits are often grouped together in units referred to as registers.

There are many different implementations of storage circuits. Some flip-flops may operate simply on the basis of the data presented, such as the Set-Reset Flip-Flop. Other flip-flops are clocked, such as the clocked D-type Flip-Flop. Clocked flip-flops are designed such that the output of the flip-flop does not reflect the data input to the flip-flop until subsequent to the assertion of a clock signal. Those skilled in the field of digital circuit design will recognize that both edge-triggered and level-triggered circuits are available for storing bits. Clocked flip-flops are particularly well-suited for use in synchronous systems.

In synchronous systems, changes in the state of a digital system are related to a clock signal. In other words, flip-flops, latches, register bits, and similar storage circuits change their outputs in a defined timing relationship with respect to the different states of the clock signal. The clock signal is essentially a reference used by circuits throughout a system, or more specifically within a clock domain, to know, for example, when input data is valid, and when new data should be presented at output terminals.

Synchronous operation of digital systems has recognized benefits and drawbacks. For example, synchronous operation along with proper design for set-up and hold times, avoids the problem of meta-stability. On the other hand, a high-frequency clock signal may have to be delivered to many parts of an integrated circuit over a long and heavily loaded path, which may create timing and/or power consumption problems.

Since it is generally important in synchronous systems to deliver the clock quickly and without uneven delay to various destinations within a clock domain, much effort has gone into trying to provide optimized clock distribution paths. These clock distribution paths are sometimes referred to clock trees. Without such careful attention to clock distribution, undesired race conditions may exist which can lead to erroneous calculations, or latching erroneous data into the storage bits of a register.

Although designers pay attention to the distribution of a clock signal within a clock domain, there exists a problem in terms of transferring data between clock domains. Since different clock domains are generally asynchronous with respect to each other, special timing problems must be overcome in order to properly operate a digital system having multiple clock domains.

In digital systems having multiple clock domains it is desirable to reduce the amount of power consumed by generating and delivering continuous clocking signals to many storage circuits; and to reliably transfer data across those clock domain boundaries.

What is needed are methods and apparatus for reducing the amount of power consumed by generating and delivering continuous clocking signals to many storage circuits; and for reliably transferring data across those clock domain boundaries.

Briefly, methods and apparatus for implementing and operating one or more pseudo-synchronous registers with reduced power consumption, and reduced complexity for transferring data between clock domains are provided. Various embodiments of the present invention replace conventional continuous clocking schemes with a strobe signal that is only generated when a data transfer operation with the one or more pseudo-synchronous registers is to take place. The strobe signal is generated so as to have a duration of one full cycle of the clock signal which defines the clock domain in which the at least one pseudo-synchronous register resides.

In a further aspect of the present invention data bits and a clock signal, both in accordance with the I2C protocol are provided to an integrated circuit having the strobe controlled pseudo-synchronous registers.

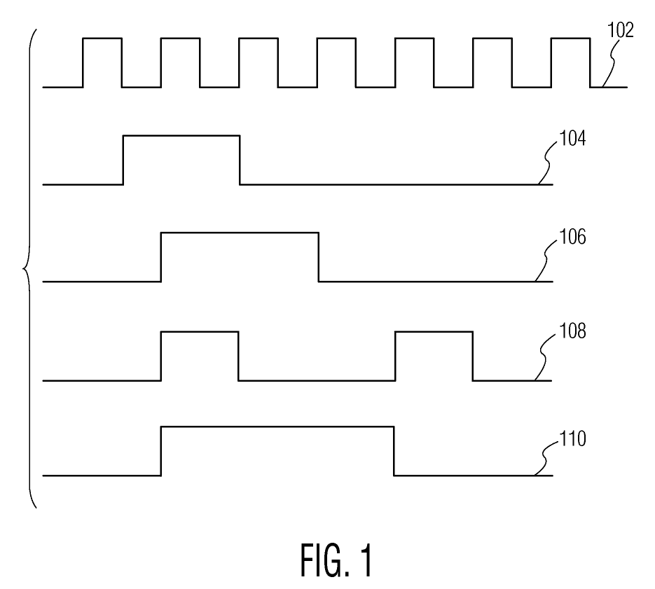

FIG. 1 is a timing diagram showing a clock signal, a data input signal, the output of a conventional register bit, and both a clock strobe and a register bit output in accordance with the present invention.

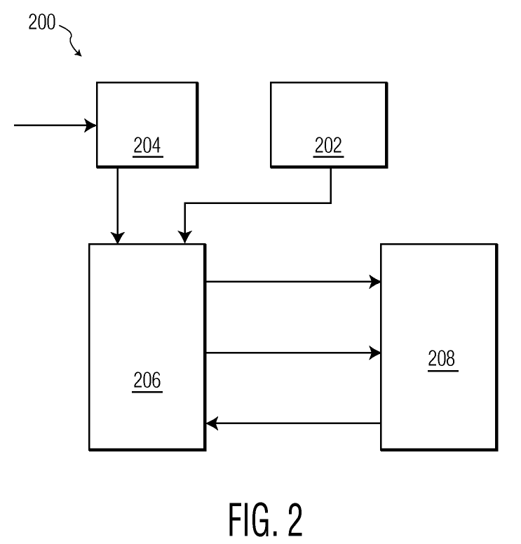

FIG. 2 is a block diagram of an illustrative digital system interfaced to an I2C bus, and further showing a register bank receiving data strobes from a control state machine.

Generally, the present invention relates to reducing power consumption by reducing the amount of clock switching that occurs at pseudo-synchronous registers.

Reference herein to “one embodiment”, “an embodiment”, or similar formulations, means that a particular feature, structure, operation, or characteristic described in connection with the embodiment, is included in at least one embodiment of the present invention. Thus, the appearances of such phrases or formulations herein are not necessarily all referring to the same embodiment. Furthermore, various particular features, structures, operations, or characteristics may be combined in any suitable manner in one or more embodiments.

The terms integrated circuit, IC, chip, die, semiconductor device, monolithic integrated circuit, microelectronic device, and similar variants may be used interchangeably herein. With respect to these microelectronic devices, signals are coupled between them and other circuit elements, including but not limited to other microelectronic devices, via physical, electrically conductive connections. The point of connection is sometimes referred to as an input, output, input/output (I/O), terminal, line, pin, pad, port, interface, or similar variants and combinations. Unless specifically noted in the context of use, these are considered equivalent terms for the purpose of this disclosure. The present invention is applicable to all the above as they are generally understood in the field.

Conventional synchronous digital integrated circuits commonly use clock trees. The clock signals delivered via these clocks trees are used for, among other things, clocking the registers in the synchronous digital integrated circuit. Register writes are done by generating an enable signal to control the D inputs of the flip-flops that are continuously clocked. In most large synchronous integrated circuit designs where the clock is always running this is an efficient method. However in very small pseudo-synchronous integrated circuit designs, this approach is not very efficient.

Various embodiments of the present invention use write strobes that are one full clock period wide in place of the continuously running clock signal. More particularly, these full period write strobes are coupled to the clock input terminals of the registers in place of the conventional clock signal. Instead of the data and enable signals going in to the D of the flip-flops, in this scheme, just the data is sent to the D of the flip-flop while the enable is used to generate a one clock period wide write strobe that is used to write, or transfer, the data into the flip-flop (which is typically part of a register).

Differences between the conventional clocked register methodology and the strobe methodology in accordance with the present invention can be seen with reference to the timing diagram of FIG. 1. FIG. 1 show a continuous period clock signal 102 having a predetermined cycle time. Although clock signal 102 is shown as having a duty cycle of approximately 50%, the present invention is not limited to any specific duty cycle for this clock signal. An input data signal 104 is also shown, and input data signal 104 is a logic high, or logic one, for approximately one and a half cycles of clock signal 102. A registered data signal 106 shows how the output of a register bit behaves with conventional clocking. It can be seen that there are many clock transitions for which the state of registered data signal 106 does not change. This results in wasted power since clock signal 102 is conventionally applied to the register without resulting in any change in state. However, with reference to clock strobe 108 and registered data output 110, in accordance with the present invention, it can be seen that there is only one clock strobe for each desired transition of the register output data 110. By reducing the number of clock transitions it is possible to reduce power consumption.

The strobe methodology of the present invention has several advantages, including but not limited to low power dissipation, easy handling of pseudo-synchronous behavior, and reduced complexity power management schemes for small simple chips that operate in systems wherein the clocks may be stopped.

With respect to low power dissipation, in systems where the registers are used only for initial setup and occasional updates, the write strobe methodology of the present invention provides a large power savings advantage. Since the registers are only clocked when they need to be accessed, and are not clocked all the time, i.e. continuously, the power saving is significant.

With respect to easy handling of pseudo-synchronous behavior, in the I2C environment, embodiments of the present invention are very efficient in dealing with the pseudo-synchronous nature of the I2C clock.

Those skilled in the art will be familiar with the well-known I2C two-wire serial bus developed by Philips, and now used by a wide variety of semiconductor manufacturers under license from Philips. The I2C protocol, which is a master/slave protocol, uses one line for serial data, which is well-known as SDA, and one line for a serial clock, which is well-known as SCL. The I2C master device produces the SCL clock signal. The I2C protocol specifies timing, addressing, clocking, data transfer, acknowledgments, voltage levels, and so on. Since the I2C two-wire serial bus is widely known and commonly available from many manufacturers, a further detailed discussion of it is not presented here.

It is noted that the I2C clock Serial Clock (SCL) is not a continuous clock. The SCL signal can be stopped and started at any time by the I2C master device. So in situations where there is another clock domain in a chip, and there is a need to synchronize signals going from a clock domain (SCL) that can be stopped at any time to another clock domain, this system works well. It works well because there is not a continuous clock running all the time to the register and hence the designer does not have to worry about potential meta-stability when the signals from the second clock domain are sent back to the SCL clock domain. A more detailed illustration of the advantages of embodiments of the present invention over conventional circuit arrangements is presented immediately below.

In illustrating the differences first let us consider how the conventional method works. A first event (A) happens in a first clock domain (clk1). Event A needs to trigger other events in a second domain (clk2). A synchronization mechanism is employed to enable this cross-domain activity. The conventional synchronization mechanism includes setting a flag (F1) in first clock domain clk1 due to Event A; double synchronizing flag F1 across to clock domain clk2 (F1qq_clk2); using flag F1qq_clk2 to set another flag (F2) in second clock domain clk2; using flag F2 to trigger events in second clock domain clk2; and once flag F2 has been captured in second clock domain clk2, the flag F1 in first clock domain clk1 is cleared.

It is in clearing the flag F1 that great care has to be taken since first clock domain clk1 can be running or may be stopped. So a fairly complex scheme has to be created to ensure safe and reliable clearing of flag F1 and thereby avoiding any meta-stable conditions. However, embodiments of the present invention do not have to be concerned with this aspect of cross-clock-domain operation since flag F1 would be set with only one clock wide strobe. This strobe will not re-occur until the entire write happens again. So the resetting of flag F1 can be done quickly and safely with less logic and more reliably.

With respect to reducing the complexity of power management schemes in small simple chips that operate in a system wherein the clocks may be stopped, stopping and starting clocks are inherently complex power management schemes for such simple chips. Embodiments of the present invention may provide much simpler and straightforward power management schemes by means of their one clock period wide write strobes.

Referring to FIG. 2, an illustrative integrated circuit 200 in accordance with the present invention is shown. An internal oscillator/clock generator 202 is provided. Clock generator 202 produces a first clock signal which defines a first clock domain. A control state machine 206 is coupled to receive the first clock signal from clock generator 202.

Control state machine 206 is further coupled to receive a clock signal from a second clock domain. In this illustrative example, the clock signal from the second clock domain is the SCL clock of an I2C master device. Integrated circuit 200 is further arranged to received an I2C input signal (SDA). Circuitry 204 determines whether the I2C master is presently addressing integrated circuit 200. If integrated circuit 200 is being addressed, then the serial data from the I2C master is passed to control state machine 206, which in turn sends the received data to register bank 208 along with a strobe signal to facilitate the transfer of data to register bank 208. The strobe signal is asserted for a duration of one cycle of the first clock signal.

Register bank 208 comprises one or more pseudo-synchronous registers. It is noted that the present invention does not require any particular size, or number of bits for register bank 208. In various embodiments of the present invention, data from register bank 208 may also be coupled back to control state machine 206.

In conventional designs, the first clock signal would be coupled to the register bank to register, or facilitate the transfer of, the data. Such an arrangement, i.e., where the first clock signal is continuously running and driving a heavy load, results in excessive power consumption relative to the functionality actually achieved. However, in various embodiments of the present invention, the strobe signals are only asserted when the data needs to be registered, thus saving power and simplifying timing relationships.

A method of using write strobes that are one full clock period wide, rather than using clocks having duration less that the full cycle time, to control the transfer of data to the registers is disclosed. Various embodiments of the present invention greatly simplify synchronization, give superior power management, and results in less chip area being consumed by the design.

A number of advantages are provided by embodiments of the present invention. One advantage is that the design of high performance circuits is facilitated by reducing the number of components required to implement a particular design.

Another advantage is that the physical size of an integrated circuit in accordance with the present invention is reduced.

Another advantage is that power management is enhanced.

It is to be understood that the present invention is not limited to the embodiments described above, but encompasses any and all embodiments within the scope of the subjoined Claims and their equivalents.

1. A method of operating an integrated circuit including one or more pseudo-synchronous registers, the method comprising:
providing a periodic clock signal, the period clock signal have a cycle of a predetermined amount of time;
receiving one or more data bits to be transferred to at least one pseudo-synchronous register;
asserting a strobe signal for a duration of one clock cycle and deasserting the strobe signal at the conclusion of the one clock cycle;
applying the one or more received data bits to a corresponding one or more data input terminals of the pseudo-synchronous register;
applying the strobe signal to a clock input terminal of the at least one pseudo-synchronous register;
transferring, responsive to the asserted strobe signal, the one or more data bits into the pseudo-synchronous register.

2. The method of claim 1, wherein the strobe signal is generated by a first circuit block, and the first circuit block is coupled to receive the period clock signal, and further coupled to provide the strobe signal to the at least one pseudo-synchronous register; and wherein the first circuit block and the at least one pseudo-synchronous register are in a first clock domain.

3. The method of claim 2, wherein one or more received data bits are received from a second clock domain.

4. The method of claim 3, wherein the first circuit block is operable to transfer the one or more received data bits to the at least one pseudo-synchronous register.

5. The method of claim 3, further comprising, receiving, at the first circuit block, a clock signal from the second clock domain, the clock signal from the second clock domain being a non-continuous clock signal.

6. The method of claim 3, wherein the one or more received data bits and the clock signal from the second clock domain are generated in accordance with the I2C protocol.

7. An integrated circuit, comprising:
a register bank, the register bank including at least one pseudo-synchronous register;
an first circuit operable to generate a periodic first clock signal, the first clock signal having a cycle of a predetermined amount of time; and
a second circuit operable to receive the first clock signal, receive one or more data bits that are to be transferred to the at least one pseudo-synchronous register, and to communicate the one or more data bits and a strobe signal to the at least one pseudo-synchronous register;
wherein the register bank, the first circuit, and the second circuit are within a first clock domain; and wherein the strobe signal is asserted for a full cycle of the first clock and then deasserted.

8. The integrated circuit of claim 7, wherein the first circuit includes and oscillator, and wherein the second circuit includes a state machine.

9. The integrated circuit of claim 8, wherein the second circuit is further operable to receive a second clock signal, the second clock signal originating from a second clock domain.

10. The integrated circuit of claim 9, wherein the second clock signal is generated external to the integrated circuit.

11. The integrated circuit of claim 10, wherein the second clock signal is not a continuous clock signal.

12. The integrated circuit of claim 9, wherein the at least one pseudo-synchronous register only receives an asserted strobe signal when data is to be transferred into the at least one pseudo-synchronous register.

13. The integrated circuit of claim 9, wherein the one or more data bits and the second clock signal are communicated to the integrated circuit in accordance with the I2C protocol.

14. The integrated circuit of claim 13, wherein the integrated circuit has a predetermined I2C address, and further comprising a third circuit coupled to the second circuit, the third circuit operable to determine whether the one or more data bits have been sent the I2C address of the integrated circuit.

15. The integrated circuit of claim 14, further comprising a synchronization flag.
